(19) United States
(12) Patent Application Publication
(10) Pub. No.: US 2025/0120285 A1
(43) Pub. Date: Apr. 10, 2025

(54) DISPLAY MODULE AND DISPLAY DEVICE

(71) Applicant: LG ELECTRONICS INC., Seoul (KR)

(72) Inventors: Guido WOO, Seoul (KR); Jungnam AN, Seoul (KR)

(73) Assignee: LG ELECTRONICS INC., Seoul (KR)

(21) Appl. No.: 18/835,971

(22) PCT Filed: Feb. 23, 2022
(86) PCT No.: PCT/KR2022/002618

§ 371 Date: Aug. 5, 2024

(30) Foreign Application Priority Data
Feb. 21, 2022 (KR) 10-2022-0022380

(51) Int. Cl. H10K 59/80; H10K 59/38; H10K 59/50

(52) U.S. Cl. CPC H10K 59/80524; H10K 59/38; H10K 59/50

(57) ABSTRACT

The present invention relates to a display module comprising: a first panel in which a plurality of pixels composed of a light-emitting unit and a light-transmitting unit are arranged in an array; and a second panel located on the rear surface of the first panel and including a plurality of light-blocking shutters corresponding to the plurality of pixels, respectively, wherein the light-blocking shutters comprise: a diffusion unit having a first thickness; a collecting unit located on one side of the diffusion unit and having a second thickness greater than the first thickness; transparent electrodes located in the diffusion unit and the collecting unit; and a first fluid and a second fluid which are located in the diffusion unit and the collecting unit and do not mix with each other. The first fluid moves between the diffusion unit and the collecting unit according to the voltage applied to the transparent electrodes, and one of the first fluid or the second fluid is transparent and the other is opaque.

### TECHNICAL FIELD

The present disclosure relates to a display module capable of controlling transmittance and a display device including the same.

### BACKGROUND ART

With growth of information society, demand for various display devices has increased. In order to satisfy such demand, in recent years, a liquid crystal display (LCD), a field emission display (FED), a plasma display panel (PDP), and an electroluminescent device have been developed as display devices.

A liquid crystal panel of the liquid crystal display includes a liquid crystal layer and a TFT substrate and a color filter substrate opposite each other in the state in which the liquid crystal layer is interposed therebetween, wherein a picture is displayed using light provided from a backlight unit.

An active matrix type organic light-emitting display has come onto the market as an example of the electroluminescent device. Since the organic light-emitting display is self-emissive, the organic light-emitting display has no backlight, compared to the liquid crystal display, and has merits in terms of response time and viewing angle, and therefore the organic light-emitting display has attracted attention as a next-generation display.

Recently, such a material as an OLED emits light by itself without a backlight structure on a backside, it may implement a bendable display panel, thereby implementing a curved display device.

Recently, display devices that provide various contents and messages through display devices rather than hardware media, such as signs and posters for outdoor advertisements, have been used. With the recent rapid development of intelligent digital imaging devices based on LEDs, OLEDs, and the like, there is a need for large display devices.

A digital signage is a representative example of a large display, and it is a display device that provides specific information as well as broadcast programs in public places such as airports, hotels, hospitals, and subway stations as a communication tool that can induce marketing, advertising, training effects, and customer experience.

In particular, video walls, which are implemented by arranging display panels in a grid to implement large display devices, are often used for outdoor advertising or large screens in large places such as exhibition halls and event halls.

Additionally, since organic light emitting diodes emit light by themselves, a transparent display may be implemented, and a large display may be applied to a window or the like using a transparent display. It is installed in a building with a curtain wall structure of a large window because it has the advantage of allowing the inflow of external light and being used as a display at the same time.

However, unlike general displays, a transparent display device fails to have a structure that reflects light in a rear direction, and there is a problem that light from the rear is emitted in a front direction, thereby resulting in poor visibility.

### DISCLOSURE

### Technical Tasks

One technical task of the present disclosure is to provide a transparent display device with improved visibility. In particular, a technical task of the present disclosure is to provide a transparent display device capable of changing transmittance.

### Technical Solutions

In one technical aspect of the present disclosure, provided is a display module including a first panel having a plurality of pixels disposed to form an array, each of the pixels including a light emitting part and a light transmitting part and a second panel disposed on a rear surface of the first panel and having a plurality of shade shutters corresponding to a plurality of the pixels, respectively, the shade shutter including a diffusing part having a first thickness, a collecting part positioned at one side of the diffusing part and having a second thickness greater than the first thickness, a transparent electrode positioned in each of the diffusing part and the collecting part, and first and second fluids positioned in the diffusing part and the collecting part so as not be mixed with each other, wherein the first fluid may move between the diffusing part or the collecting part according to a voltage applied to the transparent electrode and wherein one of the first fluid and the second fluid may be transparent while the other is opaque.

The first fluid may be opaque, the first fluid may diffuse to the diffusing part to switch the second panel to be opaque based on applying power to the transparent electrode, and the first fluid may move from the diffusing part to the collecting part based on not applying the power to the transparent electrode.

The first fluid may be transparent, and based on not applying power to the transparent electrode, the first fluid may move from the diffusing part to the collecting part to switch the second panel to be opaque.

The first fluid may be a polar fluid and the second fluid may be a non-polar fluid.

A range of the first fluid spread to the diffusing part may vary according to a magnitude of a voltage applied to the transparent electrode.

The transparent electrode may include a first transparent electrode disposed on the diffusing part and a second transparent electrode disposed in the collecting part, and based on applying power, a potential difference may be generated between the first transparent electrode and the second transparent electrode.

The collecting part may be disposed to overlap the light emitting part and smaller than the light emitting part.

The diffusing part and the collecting part may include a hydrophobic insulating layer covering the transparent electrode.

The hydrophobic insulating layer formed on the diffusing part may include an uneven portion on a surface thereof.

The shade shutter may include a partition positioned around the diffusing part to allow the first fluid positioned in the diffusing part.

The first panel may include a side wiring at an end thereof to transmit a control signal to the light emitting part and the second panel may omit the shade shutter at a position corresponding to the side wiring.

The light emitting part may include a color filter of red, blue, and green, an organic light emitting diode, and a TFT.

In another technical aspect of the present disclosure, provided is a display device including a first panel having a plurality of pixels disposed to form an array, each of the pixels including a light emitting part and a light transmitting part, a second panel disposed on a rear surface of the first panel and having a plurality of shade shutters corresponding to a plurality of the pixels, respectively, and a controller controlling the light emitting part of the first panel to output an image and controlling the shade shutters of the second panel to adjust a contrast ratio, the shade shutter including a diffusing part having a first thickness, a collecting part positioned at one side of the diffusing part and having a second thickness greater than the first thickness, a transparent electrode positioned in each of the diffusing part and the collecting part, and first and second fluids positioned in the diffusing part and the collecting part so as not be mixed with each other, wherein one of the first fluid and the second fluid may be transparent while the other is opaque and the controller may apply a power to the transparent electrode to move the first fluid from the collecting part to the diffusing part.

### Advantageous Effects

A display device of the present disclosure may adjust transparency, so that a different display effect may be produced depending on a situation.

In addition, it has the advantage of shortening a switching time of transparency and maximizing a range of change in transmissivity.

Effects obtainable from the present disclosure are not limited by the above mentioned effects, and other unmentioned effects can be clearly understood from the above description by those having ordinary skill in the technical field to which the present disclosure pertains.

### DESCRIPTION OF DRAWINGS

FIG. 1 is a block diagram illustrating each configuration of a display device of the present disclosure.

FIG. 2 is a diagram illustrating an example of a display device of the present disclosure.

FIG. 3 is a diagram for explaining brightness adjustment of a display device of the related art.

FIG. 4 is a diagram illustrating first and second panels of a display module of the present disclosure.

FIG. 5 is a cross-sectional diagram illustrating a display module of the present disclosure.

FIG. 6 is a diagram illustrating various embodiments of each pixel of a first panel of a transparent display module according to the present disclosure.

FIG. 7 is a diagram for explaining electrowetting technology.

FIG. 8 is a perspective diagram illustrating a first substrate of a shade shutter of a second panel of the display module according to the present disclosure.

FIG. 9 is a cross-sectional diagram illustrating a first embodiment of a shade shutter.

FIG. 10 is a layout illustrating a first embodiment of a shade shutter.

FIG. 11 is a cross-sectional diagram illustrating a second embodiment of a shade shutter.

FIG. 12 is a layout illustrating a second embodiment of a shade shutter.

### BEST MODE

Description will now be given in detail according to exemplary embodiments disclosed herein, with reference to the accompanying drawings. For the sake of brief description with reference to the drawings, the same or equivalent components may be provided with the same reference numbers, and description thereof will not be repeated. In general, a suffix such as “module” and “unit” may be used to refer to elements or components. Use of such a suffix herein is merely intended to facilitate description of the specification, and the suffix itself is not intended to give any special meaning or function. In the present disclosure, that which is well-known to one of ordinary skill in the relevant art has generally been omitted for the sake of brevity. The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, when an element is referred to as being “directly connected with” another element, there are no intervening elements present.

A singular representation may include a plural representation unless it represents a definitely different meaning from the context.

Terms such as “include” or “has” are used herein and should be understood that they are intended to indicate an existence of several components, functions or steps, disclosed in the specification, and it is also understood that greater or fewer components, functions, or steps may likewise be utilized.

Meanwhile, an image display device described in this specification is, for example, an intelligent image display device having a computer supporting function in addition to a broadcast reception function, wherein an Internet function may be added while the broadcast reception function is devotedly performed, whereby an interface that is more conveniently used, such as a handwriting type input device, a touchscreen, or a space remote control, may be provided. In addition, the image display device may be connected to the Internet or a computer through support of a wired or wireless Internet function, whereby various functions, such as e-mail, web browsing, banking, or gaming, may be executed. For such various functions, a standardized general-purpose OS may be used.

In the image display device described in the present disclosure, therefore, various applications may be freely added or deleted, for example, on a general-purpose OS kernel, whereby various user friendly functions may be executed. More specifically, the image display device may be a network TV, an Hbb TV, or a smart TV, and is applicable to a smartphone depending on circumstances.

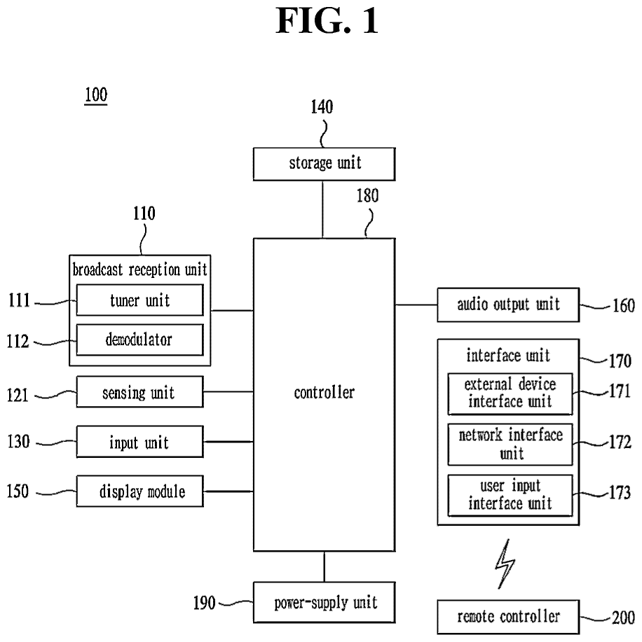

FIG. 1 is a block diagram illustrating components of a display device 100. The display device 100 may include a broadcast reception unit 110, an external device interface unit 171, a network interface unit 172, a storage unit 140, a user input interface unit 173, an input unit 130, a controller 180, a display module 150, an audio output unit 160, and/or a power supply unit 190.

The broadcast reception unit 110 may include a tuner unit 111 and a demodulation unit 112.

Unlike the figure, on the other hand, the display device 100 may include only the external device interface unit 171 and the network interface unit 172, among the broadcast reception unit 110, the external device interface unit 171, and the network interface unit 172. That is, the display device 100 may not include the broadcast reception unit 110.

The tuner unit 111 may select a broadcast signal corresponding to a channel selected by a user or any one of all pre-stored channels, among broadcast signals received through an antenna (not shown) or a cable (not shown). The tuner unit 111 may convert the selected broadcast signal into an intermediate frequency signal or a baseband video or audio signal.

For example, when the selected broadcast signal is a digital broadcast signal, the tuner unit 111 may convert the broadcast signal into a digital IF (DIF) signal, and when the selected broadcast signal is an analog broadcast signal, the tuner unit 111 may convert the broadcast signal into an analog baseband video or audio (CVBS/SIF) signal. That is, the tuner unit 111 may process the digital broadcast signal or the analog broadcast signal. The analog baseband video or audio (CVBS/SIF) signal output from the tuner unit 111 may be directly input to the controller 180.

Meanwhile, the tuner unit 111 may sequentially select broadcast signals of all broadcast channels stored through a channel memory function, among received broadcast signals, and may convert each of the selected broadcast signals into an intermediate frequency signal or a baseband video or audio signal.

Meanwhile, the tuner unit 111 may include a plurality of tuners in order to receive broadcast signals of a plurality of channels. Alternatively, a single tuner may simultaneously receive broadcast signals of a plurality of channels.

The demodulation unit 112 may receive the digital IF (DIF) signal converted by the tuner unit 111, and may perform demodulation. After performing demodulation and channel decryption, the demodulation unit 112 may output a stream signal (TS). At this time, the stream signal may be a multiplexed image, audio, or data signal.

The stream signal output from the demodulation unit 112 may be input to the controller 180. After performing demultiplexing and image/audio signal processing, the controller 180 may output an image through the display module 150, and may output audio through the audio output unit 160.

The sensing unit 120 is a device configured to sense change inside or outside the display device 100. For example, the sensing unit 120 may include at least one of a proximity sensor, an illumination sensor, a touch sensor, an infrared (IR) sensor, an ultrasonic sensor, an optical sensor (e.g. a camera), an audio sensor (e.g. a microphone), a battery gauge, and an environmental sensor (e.g. a hygrometer or a thermometer).

The controller 180 may check the state of the display device 100 based on information collected by the sensing unit, and when a problem occurs, may inform a user of the same or may solve the problem, whereby the controller may perform control such that the display device is maintained in the best state.

In addition, the controller may differently control the content, quality, and size of an image provided to the display module 150 based on a viewer or ambient light sensed by the sensing unit in order to provide the optimum viewing environment. With progress of a smart TV, a large number of functions have been loaded in the display device, and the sensing unit 20 has also been increased in number.

The input unit 130 may be provided at one side of a main body of the display device 100. For example, the input unit 130 may include a touchpad or a physical button. The input unit 130 may receive various user commands related to the operation of the display device 100, and may transmit control signals corresponding to the received commands to the controller 180.

With a decrease in size of a bezel of the display device 100, many display devices 100 have been configured such that the number of physical button type input units 130 exposed to the outside is minimized in recent years. Instead, a minimum number of physical buttons is located at the rear surface or the side surface of the display device, and the display device may receive user input through the touchpad or the user input interface unit 173, a description of which will follow, using a remote controller 200.

The storage unit 140 may store programs for signal processing and control in the controller 180, and may store a processed image, audio, or data signal. For example, the storage unit 140 may store application programs designed to execute various tasks that can be processed by the controller 180, and may selectively provide some of the stored application programs in response to request of the controller 180.

Programs stored in the storage unit 140 are not particularly restricted as long as the programs can be executed by the controller 180. The storage unit 140 may temporarily store an image, audio, or data signal received from an external device through the external device interface unit 171. The storage unit 140 may store information about a predetermined broadcast channel through a channel memory function, such as a channel map.

FIG. 1 shows an embodiment in which the storage unit 140 and the controller 180 are separately provided; however, the present disclosure is not limited thereto. The storage unit 140 may be included in the controller 180.

The storage unit 140 may include at least one of a volatile memory (e.g. DRAM, SRAM, or SDRAM), a nonvolatile memory (e.g. flash memory), a hard disk drive (HDD), and a solid-state drive (SSD).

The display module 150 may convert an image signal, a data signal, an OSD signal, and a control signal processed by the controller 180 or an image signal, a data signal, and a control signal received from the interface unit 171 to generate a driving signal. The display module 150 may include a display panel 181 having a plurality of pixels.

Each of the plurality of pixels in the display panel may include RGB subpixels. Alternatively, each of the plurality of pixels in the display panel may include RGBW subpixels. The display module 150 may convert an image signal, a data signal, an OSD signal, and a control signal processed by the controller 180 to generate a driving signal for the plurality of pixels.

A plasma display panel (PDP), a liquid crystal display (LCD), an organic light-emitting diode (OLED), or a flexible display may be used as the display module 150, and a 3D display may also be used. The 3D display 130 may be classified as a non-glasses type display or a glasses type display.

The display device includes a display module, which occupies a major portion of the front surface thereof, and a case configured to cover the rear surface and the side surface of the display module, the case being configured to package the display module.

In recent years, the display device 100 has used a flexible display module 150, such as light-emitting diodes (LED) or organic light-emitting diodes (OLED), in order to implement a curved screen.

Light is supplied to an LCD, which was mainly used conventionally, through a backlight unit, since the LCD is not self-emissive. The backlight unit is a device that supplies light emitted from a light source to a liquid crystal uniformly located in front thereof. As the backlight unit has been gradually thinned, a thin LCD has been implemented. However, it is difficult to implement the backlight unit using a flexible material. If the backlight unit is curved, it is difficult to supply uniform light to the liquid crystal, whereby the brightness of a screen is changed.

In contrast, the LED or the OLED may be implemented so as to be curved, since an element constituting each pixel is self-emissive, and therefore no backlight unit is used. In addition, since each element is self-emissive, the brightness of the element is not affected even though the positional relationship between adjacent elements is changed, and therefore it is possible to implement a curved display module 150 using the LED or the OLED.

An organic light-emitting diode (OLED) panel appeared in earnest in mid 2010 and has rapidly replaced the LCD in the small-or medium-sized display market. The OLED is a display manufactured using a self-emissive phenomenon of an organic compound in which the organic compound emits light when current flows in the organic compound. The response time of the OLED is shorter than the response time of the LCD, and therefore afterimages hardly appear when video is implemented.

The OLED is an emissive display product that uses three fluorescent organic compounds having a self-emissive function, such as red, green, and blue fluorescent organic compounds and that uses a phenomenon in which electrons injected at a negative electrode and a positive electrode and particles having positive charges are combined in the organic compounds to emit light, and therefore a backlight unit, which deteriorates color, is not needed.

A light-emitting diode (LED) panel is based on technology of using one LED element as one pixel. Since it is possible to reduce the size of the LED element, compared to a conventional device, it is possible to implement a curved display module 150. The conventional device, which is called an LED TV, uses the LED as a light source of a backlight unit that supplies light to the LCD, and therefore the LED does not constitute a screen.

When a backlight-free display module is formed on a transparent substrate, a transparent screen may be implemented when an image is not outputted.

The display module includes a display panel and a coupling magnet, a first power supply unit, and a first signal module located at a rear surface of the display panel. The display panel may include a plurality of pixels R, G, and B. The plurality of pixels R, G, and B may be formed at intersections between a plurality of data lines and a plurality of gate lines. The plurality of pixels R, G, and B may be disposed or arranged in a matrix form.

For example, the plurality of pixels R, G, and B may include a red subpixel ‘R’, a green subpixel ‘G’, and a blue subpixel ‘B’. The plurality of pixels R, G, and B may include a white subpixel ‘W’.

The side of the display module 150 on which a picture is displayed may be referred to as a front side or a front surface. When the display module 150 displays the picture, the side of the display module 150 from which the picture cannot be viewed may be referred to as a rear side or a rear surface. Meanwhile, the display module 150 may be constituted by a touchscreen, whereby an input device may also be used in addition to an output device.

The audio output unit 160 receives an audio signal processed by the controller 180 and outputs the same as audio.

The interface unit 170 serves as a path to various kinds of external devices connected to the display device 100. The interface unit may include a wireless system using an antenna as well as a wired system configured to transmit and receive data through a cable.

The interface unit 170 may include at least one of a wired/wireless headset port, an external charger port, a wired/wireless data port, a memory card port, a port for connection with a device having an identification module, an audio input/output (I/O) port, a video input/output (I/O) port, and an earphone port.

The broadcast reception unit 110 may be included as an example of the wireless system, and a mobile communication signal, a short-range communication signal, and a wireless Internet signal as well as a broadcast signal may be included.

The external device interface unit 171 may transmit or receive data to or from a connected external device. To this end, the external device interface unit 171 may include an A/V input and output unit (not shown).

The external device interface unit 171 may be connected to an external device, such as a digital versatile disc (DVD) player, a Blu-ray player, a game console, a camera, a camcorder, a computer (laptop computer), or a set-top box, in wired/wireless manner, and may perform input/output operation for the external device.

In addition, the external device interface unit 171 may establish a communication network with various remote controllers 200 in order to receive a control signal related to the operation of the display device 100 from each remote controller 200 or to transmit data related to the operation of the display device 100 to each remote controller 200.

The external device interface unit 171 may include a wireless communication unit (not shown) for short-range wireless communication with another electronic device. The external device interface unit 171 may exchange data with a mobile terminal adjacent thereto through the wireless communication unit (not shown). Particularly, in a mirroring mode, the external device interface unit 171 may receive device information, information of an application that is executed, and an image of the application from the mobile terminal.

The network interface unit 172 may provide an interface for connection of the display device 100 with a wired/wireless network including the Internet. For example, the network interface unit 172 may receive content or data provided by an Internet or content provider or a network operator through the network. Meanwhile, the network interface unit 172 may include a communication module (not shown) for connection with the wired/wireless network.

The external device interface unit 171 and/or the network interface unit 172 may include a communication module for short-range communication, such as Wi-Fi, Bluetooth, Bluetooth Low Energy (BLE), ZigBee, or Near Field Communication (NFC), or a communication module for cellular communication, such as Long-Term Evolution (LTE), LTE Advance (LTE-A), Code Division Multiple Access (CDMA), Wideband CDMA (WCDMA), Universal Mobile Telecommunications System (UMTS), or Wireless Broadband (WiBro).

The user input interface unit 173 may transmit a user input signal to the controller 180, or may transmit a signal from the controller 180 to a user. For example, the user input interface unit may transmit/receive a user input signal, such as power on/off, channel selection, or screen setting, to/from the remote controller 200, may transmit a user input signal, such as a power key, a channel key, a volume key, or a setting value, input from a local key (not shown) to the controller 180, may transmit a user input signal input from a sensor unit (not shown) configured to sense user gesture to the controller 180, or may transmit a signal from the controller 180 to the sensor unit.

The controller 180 may include at least one processor, and may control the overall operation of the display device 100 using the processor included therein. Here, the processor may be a general processor, such as a central processing unit (CPU). Of course, the processor may be a dedicated device, such as an ASIC, or another hardware-based processor.

The controller 180 may demultiplex a stream input through the tuner unit 111, the demodulation unit 112, the external device interface unit 171, or the network interface unit 172, or may process demultiplexed signals to generate and output a signal for image or audio output.

An image signal processed by the controller 180 may be input to the display module 150, which may display an image corresponding to the image signal. In addition, the image signal processed by the controller 180 may be input to an external output device through the external device interface unit 171.

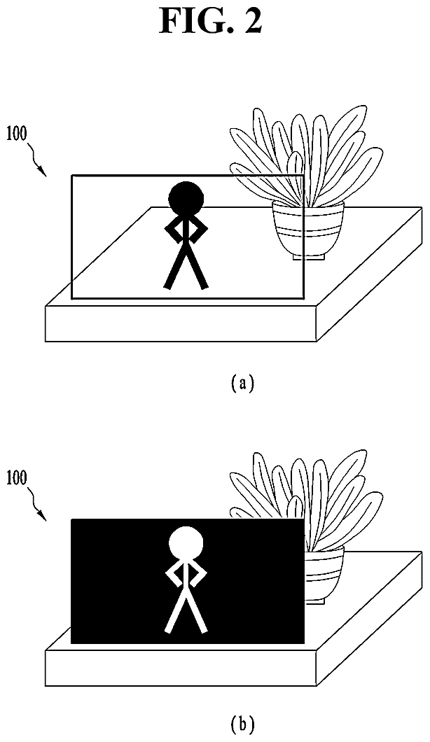

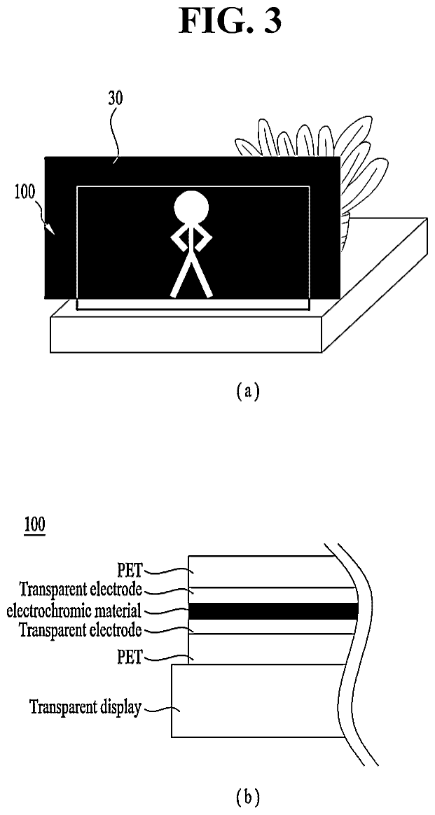

An audio signal processed by the controller 180 may be output through the audio output unit 160. In addition, the audio signal processed by the controller 180 may be input to an external output device through the external device interface unit 171. Although not shown in FIG. 2, the controller 180 may include a demultiplexing unit, an image processing unit, and the like, which will be described below with reference to FIG. 3.

Further, the controller 180 may control the overall operation of the display device 100. For example, the controller 180 may control the tuner unit 111 such that a broadcast corresponding to a channel selected by a user or a pre-stored channel is tuned.

In addition, the controller 180 may control the display device 100 according to a user command input through the user input interface unit 173 or an internal program. Meanwhile, the controller 180 may control the display module 150 to display an image. At this time, the image displayed on the display module 150 may be a still image or video, or may be a 2D image or a 3D image.

Meanwhile, the controller 180 may perform control such that a predetermined 2D object is displayed in an image displayed on the display module 150. For example, the object may be at least one of a connected web screen (newspaper or magazine), an electronic program guide (EPG), various menus, a widget, an icon, a still image, video, and text.

Meanwhile, the controller 180 may modulate and/or demodulate a signal using an amplitude shift keying (ASK) method. Here, the amplitude shift keying (ASK) method may be a method of changing the amplitude of a carrier depending on a data value to modulate a signal or restoring an analog signal to a digital data value depending on the amplitude of a carrier.

For example, the controller 180 may modulate an image signal using the amplitude shift keying (ASK) method, and may transmit the modulated image signal through a wireless communication module.

For example, the controller 180 may demodulate and process an image signal received through the wireless communication module using the amplitude shift keying (ASK) method.

As a result, the display device 100 may easily transmit and receive a signal to and from another image display device disposed adjacent thereto without using a unique identifier, such as a media access control (MAC) address, or a complicated communication protocol, such as TCP/IP.

Meanwhile, the display device 100 may further include a photographing unit (not shown). The photographing unit may photograph a user. The photographing unit may be implemented by one camera; however, the present disclosure is not limited thereto. The photographing unit may be implemented by a plurality of cameras. Meanwhile, the photographing unit may be embedded in the display device 100 above the display module 150, or may be separately disposed. Image information photographed by the photographing unit may be input to the controller 180.

The controller 180 may recognize the location of a user based on an image captured by the photographing unit. For example, the controller 180 may recognize the distance between the user and the display device 100 (z-axis coordinate). Further, the controller 180 may recognize an x-axis coordinate and a y-axis coordinate in the display module 150 corresponding to the location of the user.

The controller 180 may sense user gesture based on the image captured by the photographing unit, a signal sensed by the sensor unit, or a combination thereof.

The power supply unit 190 may supply power to the components of the display device 100. In particular, the power supply unit may supply power to the controller 180, which may be implemented in the form of a system on chip (SOC), the display module 150 for image display, and the audio output unit 160 for audio output.

Specifically, the power supply unit 190 may include an AC/DC converter (not shown) configured to convert AC power into DC power and a DC/DC converter (not shown) configured to convert the level of the DC power.

Meanwhile, the power supply unit 190 serves to distribute power supplied from the outside to the respective components of the display device. The power supply unit 190 may be directly connected to an external power supply in order to supply AC power, or may include a battery so as to be used by charging.

In the former case, a cable is used, and the power supply unit is difficult to move or the movement range of the power supply unit is limited. In the latter case, the power supply unit is free to move, but the weight of the power supply unit is increased in proportion to the weight of the battery, the volume of the power supply unit is increased, and, for charging, the power supply unit must be directly connected to a power cable or must be coupled to a charging holder (not shown) that supplies power for a predetermined time.

The charging holder may be connected to the display device through a terminal exposed to the outside, or the battery mounted in the power supply unit may be charged in a wireless manner when the power supply unit approaches the charging holder.

The remote controller 200 may transmit user input to the user input interface unit 173. To this end, the remote controller 200 may use Bluetooth communication, radio frequency (RF) communication, infrared radiation communication, ultra-wideband (UWB) communication, or ZigBee communication. In addition, the remote controller 200 may receive an image, audio, or data signal output from the user input interface unit 173 so as to be displayed thereon or audibly output therefrom.

Meanwhile, the display device 100 may be a stationary or movable digital broadcast receiver capable of receiving a digital broadcast.

Meanwhile, the block diagram of the display device 100 shown in FIG. 1 is for an embodiment of the present disclosure, and elements of the block diagram may be integrated, added, or omitted depending on specifications of an actually implemented display device 100.

That is, two or more elements may be integrated into one element, or one element may be divided into two or more elements, as needed. In addition, the function performed by each block is for describing the embodiment of the present disclosure, and the specific operations and components thereof do not limit the scope of rights of the present disclosure.

FIG. 2 is a diagram illustrating an example of a display device 100 of the present disclosure.

Since an object behind the transparent display device 100 is seen, an image outputted on a display module may be displayed while overlapping with the object located behind, which may be in harmony with surrounding objects. In addition, when the transparent display device 100 is not in use, a black screen does not take up a large amount of space, and a rear surface may be seen in a transparent state to give an open feeling.

In addition, the transparent display device 100 is a display device 100 in the form of increasing utilization recently by installing the transparent display device 100 on a window, etc. to output an image while allowing light to flow in.

However, the transparent display device 100 has a problem in that light introduced from the rear surface is emitted to the front surface and the image outputted from the display module 150 is not reflected from the rear surface, so that it cannot reach a user in a front direction. Namely, there is a problem in failing to obtain a clear screen due to a lowered contrast ratio.

Accordingly, a panel for selectively shielding light may be provided on the rear surface to be switched from a transparent state as shown in (a) to an opaque state as shown in (b). Transparency may be adjusted to provide a clear screen.

FIG. 3 is a diagram to explain the brightness adjustment of the display device 100 of the related art, (a) shows an example in which a shade panel corresponding to a size of the display module 150 is placed on a rear surface of the display module 150 and an embodiments in which a shade panel capable of adjusting transparency by an electrical signal is provided.

The same type as (a) requires a driving unit such as a motor to physically place the shade panel on the rear surface of the display module 150 and a separate structure to accommodate the shade panel and has a problem that it takes time to dispose and remove the shade panel.

As shown in (b), the shade panel including an electrochromic material may adjust transparency through transparent electrodes on both sides thereof. An example of the electrochromic material may be a liquid crystal. However, such an electrochromic material has a limited effect of improving a contrast ratio because a transmissivity variation width is up to 45%. In addition, there is a problem that it is difficult to implement a large panel.

Accordingly, the present disclosure provides a display module 300 including a shade panel using a shade shutter 321.

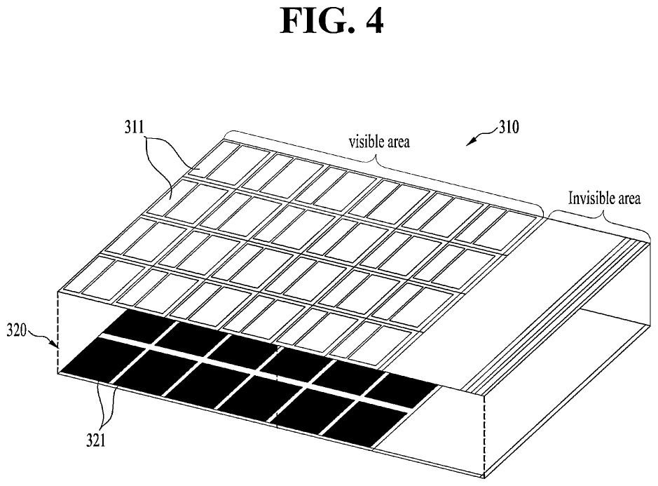

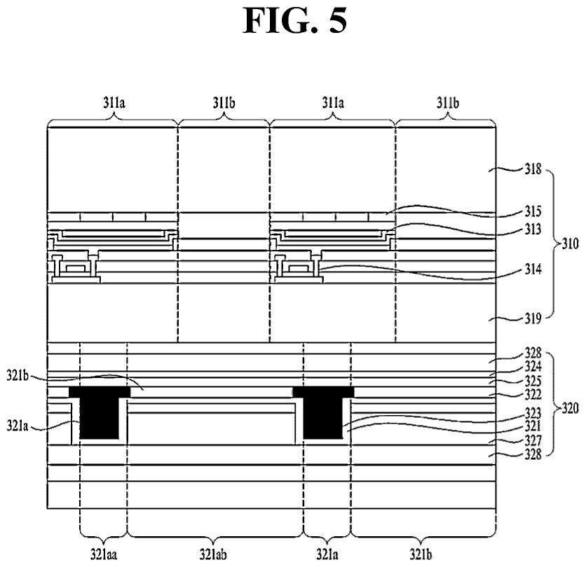

FIG. 4 is a diagram illustrating first and second panels 310 and 320 of the display module 300 of the present disclosure. FIG. 5 is a cross-sectional diagram thereof, in which a portion of the display device 100 may be enlarged to include a display area in which an image is outputted and a non-display area in which a side wiring and the like are disposed.

Referring to FIG. 4 and FIG. 5, the display device 100 of the present disclosure may include a first panel 310 through which an image is outputted and a second panel 320 positioned on a rear surface of the first panel 310 to adjust transparency. The first panel 310 includes a plurality of pixels 311, and a shade shutter 321 may be disposed corresponding to each of the pixels 311.

Each of the pixels 311 includes a light emitting part 311a and a light transmitting part 311b, and the shade shutter 321 of the second panel 320 includes a collecting part 321a and a diffusing part 321b. The collecting part 321a of the shade shutter 321 is disposed at a position corresponding to the light emitting part 311a, and the diffusing part 321b of the shade shutter 321 may have a size larger than that of the light transmitting part 311b of the first panel.

The collecting part 321a may be disposed at a position corresponding to the light emitting part 311a, and the diffusing part 321b may be disposed at a position corresponding to the light transmitting part 311b.

As a size of the collecting part 321a is smaller than that of the light emitting part 311a, the collecting part 321a may be covered by the light emitting part 311a. In addition, the diffusing part 321b may be formed larger than the light transmitting part 311b. Accordingly, the diffusing part 321b may partially overlap the light emitting part 311a as well as the light transmitting part 311b.

Since one pixel of the first panel 310 and one shade shutter 321 of the second panel 320 have the same size, a sum of the size of the light emitting part 311a and the size of the light transmitting part 311b corresponds to a sum of the size of the collecting part 321a and the size of the diffusing part 321b.

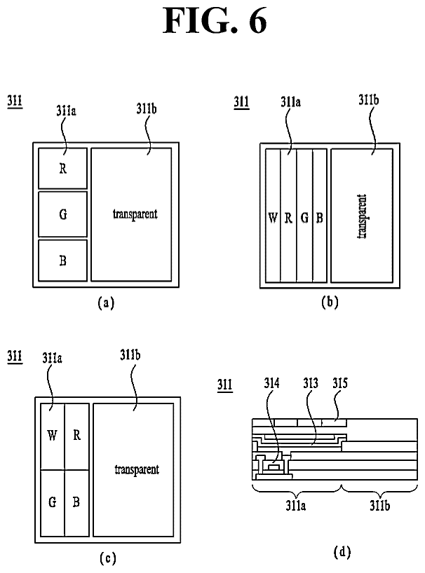

FIG. 6 is a diagram illustrating various embodiments of each pixel 311 of a first panel 310 of a transparent display device 100 according to the present disclosure. Each of the pixels 311 of the first panel 310 includes a light emitting part 311a and a light transmitting part 311b. The light emitting part 311a is divided into red, blue, and green to represent colors, and may include white. The light transmitting part 311b may be disposed adjacent to the light emitting part 311a and may include a transparent material that transmits light on a rear surface thereof.

A user may simultaneously appreciate an image through the light emitted from the light emitting part 311a and view an object on the rear surface through the light transmitting part 311b. If an area of the transparent unit is too large, it causes a problem that a size of the pixel 311 increases, and thus an area ratio of the light transmitting part 311b and the light emitting part 311a may be configured to be around 50%.

For example, in the case of a 77-inch display module 150, if a width of one pixel 311 is implemented as 444 um and a width of the transparent part is designed as 200 μm, the transparent part may have an area of about 45% per pixel 311.

The light emitting part 311a may be disposed side by side in a vertical direction as shown in FIG. 6(a) or in a horizontal direction as shown in FIG. 6(b), or may be implemented as an array as shown in FIG. 6(c). A vertical structure of the light emitting part 311a may be configured to have a layered structure of a color filter 315, an organic light emitting diode 313, and a Thin Film Transistor (TFT) 314 on a transparent substrate 325 as shown in FIG. 6(d).

The color filter 315 may include three colors or four colors including white to implement the color per the pixel 311 described above, and a light source that emits light may be included on a rear surface of the color filter 315. As a switch for controlling ON/OFF of the light source, a single TFT 313 may be disposed per the pixel 311.

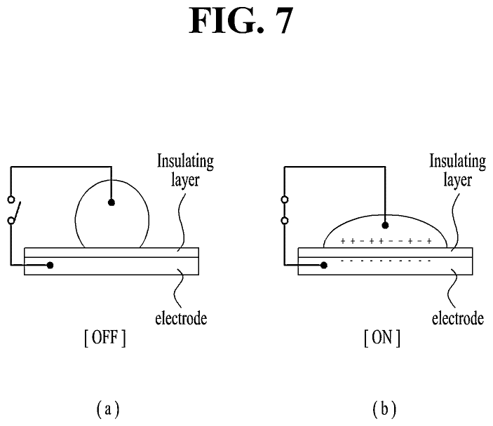

FIG. 7 is a diagram for explaining an electrowetting technology. Electrowetting technology is a technology for applying power to a polar fluid such as water so that molecules of the polar fluid move according to the flow of current, thereby changing surface tension.

Since the molecules themselves have polarity, the arrangement of molecules may vary according to the flow of current when electricity flows. Since it is a fluid, molecules of the polar fluid can move in an electrode direction.

When the polar fluid comes into direct contact with an electrode, electrolysis occurs and water is decomposed into hydrogen and oxygen. If an insulating layer is formed on the electrode to prevent electrolysis, electrons cannot be exchanged because it does not come into contact with the electrode, which is a metal, so electrolysis does not occur and only surface tension may change due to the influence of an electric field.

According to the use of the electrowetting technology, the polar fluid may be deformed such that a size of a surface area thereof varies depending on whether or not power is applied. When power is not applied, the polar fluid is gathered in a circle as shown in FIG. 7(a) to minimize the surface area as possible.

When power is applied, a shape of a first fluid 323 is flatly deformed so that the electric charge inside the first fluid 323 is in close contact with the electrode, and a surface area of the first fluid 323 is widened as shown in FIG. 7(b). The fluid may be moved depending on whether or not power is applied by using the electrowetting technology.

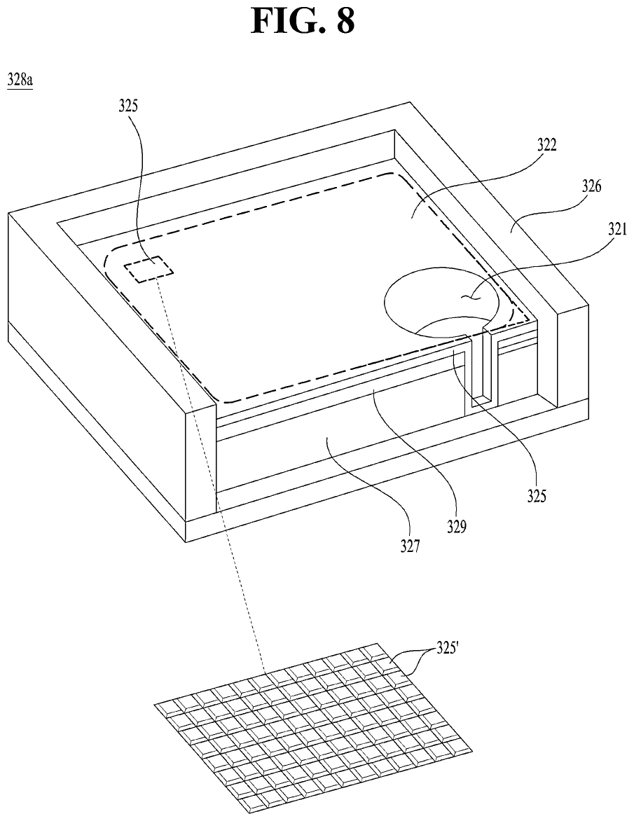

FIG. 8 is a diagram illustrating a first substrate of the shade shutter 321 of the second panel 320 of the display module according to the present disclosure. The shade shutter 321 may include the diffusing part 321b, the collecting part 321a, and the first fluid 323 and the second fluid 324 provided between the diffusing part 321b and the collecting part 321a.

The collecting part 321a may be disposed at a position corresponding to the light emitting part 311a of the first panel 310, and the diffusing part 321b may be disposed at a position corresponding to the light transmitting part 311b of the first panel 310. As a size of the collecting part 321a is smaller than that of the light emitting part 311a, the collecting part 321a may be covered by the light emitting part 311a. In addition, the diffusing part 321b may be formed larger than the light transmitting part 311b.

The diffusing part 321b has a wide area in a horizontal direction and is a space narrow in a vertical direction. The collecting part 321a is a space formed to have a larger thickness in the vertical direction from one side of the diffusing part 321b. Accordingly, the diffusing part 321b and the collecting part 321a are similar in volume, but a surface area of the diffusing part 321b is wider.

The second panel 320 may be configured in a manner of disposing a pair of transparent substrates 328a and 328b to face each other. A transparent electrode 329 may be formed on the transparent substrates 328a and 328b, and the transparent substrates 328a and 328b may be disposed to allow the transparent electrodes 329 to face each other, thereby forming the diffusing part 321b and the collecting part 321a.

FIG. 8 is a diagram illustrating the first transparent substrate 328a including the collecting part 321a formed to be concave on one side of the diffusing part 321b in a pair of the transparent substrates 328a and 328b. The collecting part 321a may be formed by forming a portion of the first transparent substrate 328a to be concave.

The collecting part 321a may be configured in a manner of forming a recess in a thick substrate, or may be configured in the form of a mesa 327 by stacking a transparent material on the rest of the parts except the collecting part 321a.

A photoresist such as SU-8 that may be thickly stacked may be used to form the mesa 327. The SU-8 is an epoxy-based photoresist, is cured by cross-linking a portion exposed to UV, and is stacked in a portion other than the collecting part 321a in FIG. 8 to form a mesa 327. In addition, an upper portion of the mesa becomes the diffusing part 321b.

To partition each shade shutter 321, a partition 326 may be formed around the diffusing part 321b, and the partition 326 may be formed on the first transparent substrate 328a. An end portion of the partition 326 may be in contact with the second transparent substrate 328b to form a gap with the first transparent substrate 328a, and the diffusing part 321b may be formed by the gap between the first transparent substrate 328a and the second transparent substrate 328b.

A vertical size of the collecting part 321a may have a depth several times or more than ten times that of the gap between the first transparent substrate 328a and the second transparent substrate 328b. The collecting part 321a may have a hexahedral shape or a cylindrical shape.

The first transparent substrate 328a and the second transparent substrate 328b include a transparent electrode 329, and may be disposed so that the transparent electrode 329 faces each other. The transparent electrode 329 may be formed using Indium Tin Oxide (ITO).

The transparent electrode 329 may include a first transparent electrode 3291 positioned at the diffusing part 321b and a second transparent electrode 3292 positioned at the collecting part 321a, and the first transparent electrode 3291 may be formed as a cathode and the second transparent electrode 3292 may be formed as an anode. When power is applied, a potential difference occurs between the first transparent electrode 3291 and the second transparent electrode 3292.

When the transparent electrode 329 directly contacts the first fluid 323 and the second fluid 324, electrolysis may occur, and thus a hydrophobic insulating layer 325 covering the transparent electrode 329 may be provided. The hydrophobic insulating layer 325 may be formed by mixing or stacking an insulating material such as polydimethylsiloxane (PDMS) and a hydrophobic material such as Teflon.

In order for the first fluid 323 to move to the diffusing part 321b due to a repulsive force of the hydrophobic insulating layer 325, a large force is required, and thus a high voltage should be applied. As illustrated in FIG. 8, surface roughness may be increased by forming an unevenness 325′ in the hydrophobic insulating layer 325 of the diffusing part 321b so as to be driven with low power. The unevenness may be formed in both a horn shape and a shape having a flat top surface.

The first fluid 323 and the second fluid 324 are not mixed with each other. The first fluid 323 may use a polar material and the second fluid 324 may use a non-polar material. For example, the second fluid 324 may be water and the second fluid 324 may be oil.

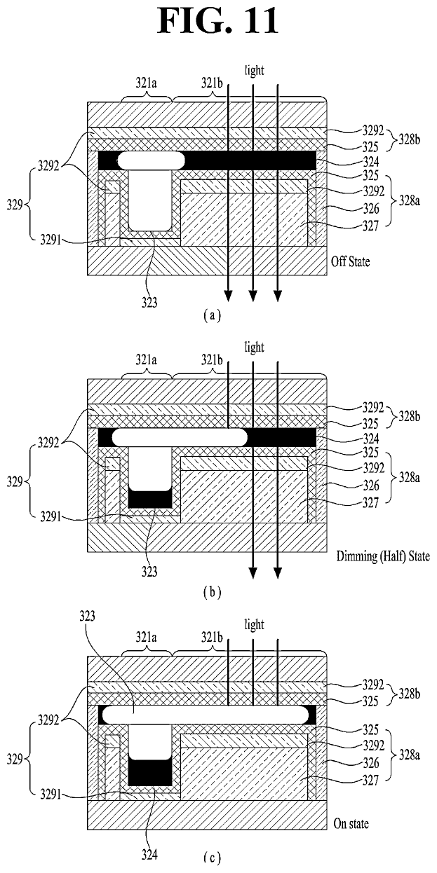

A dye may be added to one side of the first fluid 323 and the second fluid 324 to be opaque. A dye may be added to the polar first fluid 323 as in the embodiment shown in FIG. 8, or a dye may be added to the non-polar second fluid 324 as in the embodiment shown in FIG. 11.

The movement of the first fluid 323 and the second fluid 324 is not different in the two embodiments, but whether or not power is applied to switch to a transparent state is different.

The embodiment of FIG. 8 maintains a transparent state in an Off-state in which power is not applied, and becomes opaque when power is applied (On-state). On the other hand, the embodiment of FIG. 11 is different in maintaining an opaque state in an Off-state or switching to a transparent state when applying power (On-state).

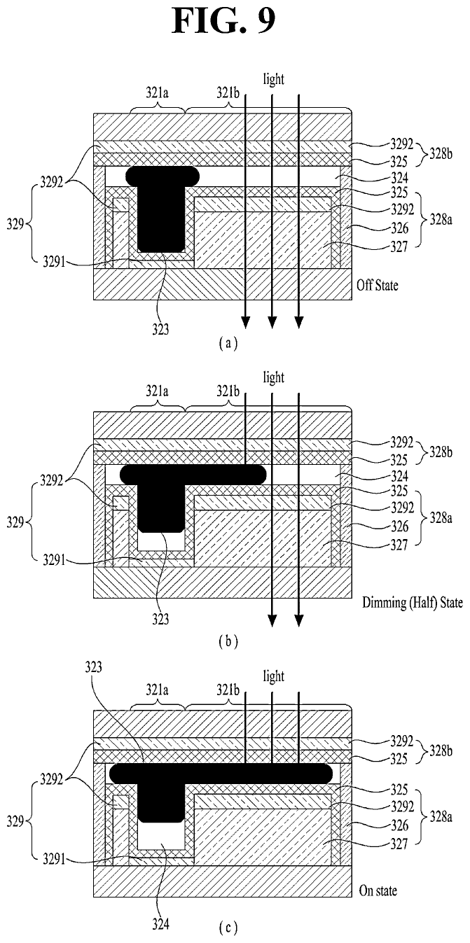

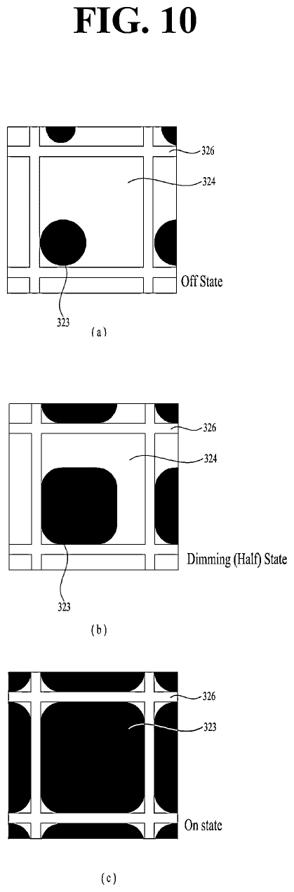

A detailed operation of the fluid will be described with reference to the respective drawings below. FIG. 9 is a cross-sectional diagram illustrating a first embodiment of the shade shutter 321, and FIG. 10 is a lay out illustrating the first embodiment of the shade shutter 321.

When power is not applied as shown in FIG. 9(a), the polar first fluid 323 has a property of maintaining a shape in which a surface area is minimized by surface tension thereof. Accordingly, the first fluid 323 is located in the collecting part 321a having a small surface area to volume, and the second fluid 234 is located in the diffusing part 321b.

When power is applied, the first transparent electrode 3291 located in the diffusing part 321b may become a cathode and the second transparent electrode 3292 located in the collecting part 321a may become an anode. When power is applied, a potential difference is generated between the collecting part 321a and the diffusing part 321b, and electric charges of the first fluid 323 receive a force directed to the first transparent electrode 3291 on the diffusing part 321b.

The first fluid 323 is in the same state as shown in (c) by expanding a surface area so as to be close to the first transparent electrode 3291 that is the cathode, and since the first fluid 323 moves to the diffusing part 321b, the second fluid 324 may be pushed to move to the collecting part 321a.

As shown in FIG. 9(b) and FIG. 9(c), the first fluid 323 may move from the collecting part 321a toward the diffusing part 321b. As the magnitude of the voltage applied to the transparent electrode 329 increases, the first fluid 323 may move to the diffusing part 321b while overcoming the surface tension of the first fluid 323.

Referring to FIG. 10, in a state in which power is not applied, the first fluid 323 is located in the collecting part 321 a so that a portion corresponding to the light transmitting part 311b becomes transparent as shown in (a). When power is applied, the first fluid 323 moves to the diffusion unit 321b to cover the light transmitting part 311b and the display module 150 becomes opaque as shown in (c). In the state as shown in (b), which is an intermediate step, the display module 150 may be in a translucent state.

FIG. 9 is a cross-sectional diagram illustrating a second embodiment of the shade shutter 321, and FIG. 10 is a layout illustrating the second embodiment of the shade shutter 321.

On the contrary, when a dye is added to the second fluid 324, it is driven in the same manner as the above-described embodiment. That is, in the state in which power is turned off, the first fluid 323 may be located in the collecting part 321a. When power is turned on, the first fluid 323 may move toward the first transparent electrode 329 to be located in the diffusing part 321b.

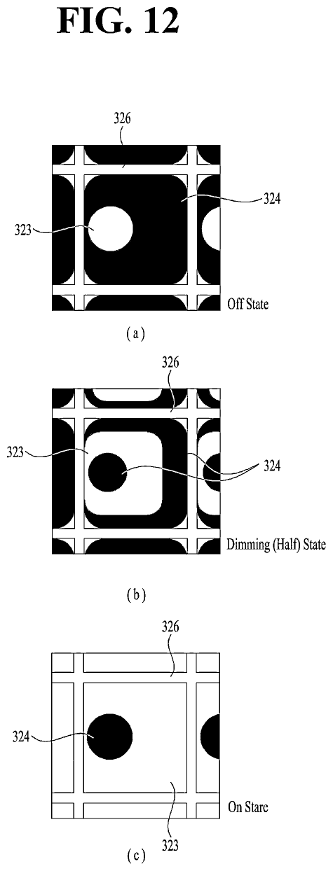

Yet, since a dye exists in the second fluid 324, the light transmitting part 311b becomes transparent as shown in FIG. 11(c) and FIG. 12(c) in the ON-state in which the power is applied. The second fluid 324 is positioned in the diffusing part 321b as shown in FIG. 11(a) and FIG. 12(a) in the OFF state, so that the display module becomes opaque. Furthermore, the collecting part 321a of the present embodiment is not positioned at one corner of the shade shutter 321, but may be positioned at a center in a second direction (vertical direction in the drawing) perpendicular to a first direction (horizontal direction in the drawing) in which the light emitting part 311a and the light transmitting part 311b are arranged side by side. The collecting part 321a may be disposed to overlap the light emitting part 311a, and the position thereof is not limited. In a half state as shown in the intermediate step (b), the display module 150 may be in a translucent state.

As described above, the display device 100 of the present disclosure may adjust the transparency, so that different display effects may be produced according to situations.

In addition, it has the advantage of shortening a switching time of transparency and maximizing the range of change in transmissivity.

The above detailed description should not be construed as being limitative in all terms, but should be considered as being illustrative. The scope of the present disclosure should be determined by reasonable analysis of the accompanying claims, and all changes in the equivalent range of the present disclosure are included in the scope of the present disclosure.

What is claimed is:

1. A display module, comprising:
a first panel having a plurality of pixels disposed to form an array, each of the pixels including a light emitting part and a light transmitting part; and
a second panel disposed on a rear surface of the first panel and having a plurality of shade shutters corresponding to a plurality of the pixels, respectively,
the shade shutter comprising:
a diffusing part having a first thickness;
a collecting part positioned at one side of the diffusing part and having a second thickness greater than the first thickness;
a transparent electrode positioned in each of the diffusing part and the collecting part; and
first and second fluids positioned in the diffusing part and the collecting part so as not be mixed with each other,
wherein the first fluid moves between the diffusing part or the collecting part according to a voltage applied to the transparent electrode and
wherein one of the first fluid and the second fluid is transparent while the other is opaque.

2. The display module of claim 1, wherein the first fluid is opaque, wherein the first fluid diffuses to the diffusing part to switch the second panel to be opaque based on applying power to the transparent electrode, and wherein the first fluid moves from the diffusing part to the collecting part based on not applying the power to the transparent electrode.

3. The display module of claim 1, wherein the first fluid is transparent and wherein based on not applying power to the transparent electrode, the first fluid moves from the diffusing part to the collecting part to switch the second panel to be opaque.

4. The display module of claim 1, wherein the first fluid is a polar fluid and wherein the second fluid is a non-polar fluid.

5. The display module of claim 1, wherein a range of the first fluid spread to the diffusing part varies according to a magnitude of a voltage applied to the transparent electrode.

6. The display module of claim 1, the transparent electrode comprising:
a first transparent electrode disposed on the diffusing part; and
a second transparent electrode disposed in the collecting part,
wherein based on applying power, a potential difference is generated between the first transparent electrode and the second transparent electrode.

7. The display module of claim 1, wherein the collecting part is disposed to overlap the light emitting part and smaller than the light emitting part.

8. The display module of claim 1, wherein the diffusing part and the collecting part include a hydrophobic insulating layer covering the transparent electrode.

9. The display module of claim 8, wherein the hydrophobic insulating layer formed on the diffusing part includes an uneven portion on a surface thereof.

10. The display module of claim 1, wherein the shade shutter comprises a partition positioned around the diffusing part to allow the first fluid positioned in the diffusing part.

11. The display module of claim 1, wherein the first panel includes a side wiring at an end thereof to transmit a control signal to the light emitting part and wherein the second panel omits the shade shutter at a position corresponding to the side wiring.

12. The display module of claim 1, wherein the light emitting part comprises a color filter of red, blue, and green, an organic light emitting diode, and a TFT.

13. A display device, comprising:
a first panel having a plurality of pixels disposed to form an array, each of the pixels including a light emitting part and a light transmitting part;
a second panel disposed on a rear surface of the first panel and having a plurality of shade shutters corresponding to a plurality of the pixels, respectively; and
a controller controlling the light emitting part of the first panel to output an image and controlling the shade shutters of the second panel to adjust a contrast ratio,
the shade shutter comprising:
a diffusing part having a first thickness;
a collecting part positioned at one side of the diffusing part and having a second thickness greater than the first thickness;
a transparent electrode positioned in each of the diffusing part and the collecting part; and
first and second fluids positioned in the diffusing part and the collecting part so as not be mixed with each other,
wherein one of the first fluid and the second fluid is transparent while the other is opaque and
wherein the controller applies a power to the transparent electrode to move the first fluid from the collecting part to the diffusing part.
